(19) United States
(12) Patent Application Publication
(10) Pub. No.: US 2006/0150404 A1
(43) Pub. Date: Jul. 13, 2006

(54) Component placement device, nozzle exchange device as well as method for the exchange of nozzles

(76) Inventor: Johannes T.A. Van De Ven, La Veldhoven (NL)

Correspondence Address: FOLEY AND LARDNER LLP;SUITE 500, 3000 K STREET NW, WASHINGTON, DC, 20007, US

(21) Appl. No.: 10/563,575

(22) PCT Filed: Jul. 21, 2004
(86) PCT No.: PCT/IB04/51270

§ 371 Date: Jan. 6, 2006

(30) Foreign Application Priority Data
Jul. 30, 2003 (EP) 03102344.3

(51) Int. Cl. H05K 3/30

(52) U.S. Cl. 29/834; 29/744; 29/833

(57) ABSTRACT

A component placement device is provided with a holder and a nozzle which is detachably connected to the holder. The nozzle which is provided with a duct, is exchangeable by means of a nozzle exchange device. The holder is furthermore provided with a passage that is connected to the duct.

The invention relates to a component placement device which has a holder and a nozzle connected to the holder and provided with a duct.

The invention further relates to a nozzle exchange device.

The invention also relates to a method for the exchange of nozzles.

In a similar assembly known from United States patent U.S. Pat. No. 5,831,504 for component placement, a nozzle extending along an axis is slidably disposed in a holder. In a duct extending through the nozzle a vacuum is built up by means of which a component is picked up by the nozzle and placed on a substrate. If relatively large forces directed parallel to the axis are exerted on the nozzle, the nozzle is slid into the holder so that the maximum force exerted on the component is limited.

If undesired forces in a radial direction transverse to the axis are exerted on the nozzle, the nozzle will deform or break off. A further disadvantage of such a known assembly is that a nozzle cannot be exchanged. In addition, between the nozzle and holder which can be moved relative to each other there may be wear and contamination, which is undesired.

It is an object of the present invention to provide a device whose nozzle can be separated from the holder in a simple manner.

This object is achieved by the device according to the invention in that the nozzle is detachably connected to the holder, which holder has a passage extending coaxially to the duct.

The device according to the invention is advantageous in that various nozzles can be detachably attached to the holder, so that components of different sizes can be placed on a substrate by means of various nozzles. The vacuum needed for picking up a component can be built up through the passage in the holder and the connecting duct in the nozzle. In addition, in case of a collision of the nozzle, when forces are exerted on the nozzle in a radial direction transverse to the axis, the nozzle may be separated from the holder, so that at least damage to the holder is avoided.

An embodiment of the device according to the invention is characterized in that the nozzle, when in operation, can be decoupled from the holder in radial direction relative to the axis of the duct when a predetermined force exerted on the nozzle in radial direction is exceeded.

Such an embodiment is advantageous in that if the device accidentally collides with an object in its environment, the nozzle is separated from the holder as a result of the forces working in radial direction and resulting from the collision. Consequently, not the whole device is damaged in case of such a collision, but only the relatively cheap nozzle is separated from the device. Furthermore, the possibly damaged nozzle can quickly be replaced, so that continuous use of the device remains guaranteed.

Another embodiment of the device according to the invention is characterized in that the nozzle can be detachably attached to the holder by means of at least one magnet.

The holder and the nozzle are connected to each other in a simple manner by means of a magnet. Furthermore, the magnetic force can be predetermined, so that the force necessary for separating the nozzle from the holder is known.

A still further embodiment of the device according to the invention is characterized in that the holder and the nozzle can be aligned to each other.

By aligning them, the duct of the nozzle and the passage of the holder can be accurately connected, so that a proper vacuum in the duct and the passage can be built up.

A further embodiment of the device according to the invention is characterized in that the holder and three radially extending grooves in the holder and in the nozzle are located apart, with a sphere being located between opposite grooves in the holder and the nozzle.

As a result of the grooves collaborating by means of the sphere, the holder and the nozzle can be aligned to each other in a relatively simple and fast manner.

A still further embodiment of the device according to the invention is characterized in that in the holder and the nozzle three grooves are 120 degrees apart.

As a result of such a spreading of the grooves, the holder and the nozzle fit together in a number of ways and can therefore be aligned to each other in a simple manner.

A still further embodiment of the device according to the invention is characterized in that the duct and/or passage have/has a filter.

Such an embodiment is advantageous in that the air sucked in as a result of the vacuum in the duct and the passage is filtered, so that the duct, the passage and the vacuum pump connected to the passage will not be contaminated or even clogged.

A still further embodiment of the device according to the invention is characterized in that the nozzle includes an identification means.

An advantage of such an embodiment is that various nozzles can be simply recognized. The identification means may be, for example, a bar code, dot code or alphanumeric code which can be recognized by means of a CCD camera or laser. An alphanumeric code is advantageous in that it can be read by a human being also without an aid, which may be of advantage when the nozzle is fitted for the first time.

It is alternatively possible to provide each nozzle with a unique section at a predetermined spot, which section can easily be determined and verified by means of a camera or laser.

A still further embodiment of the device according to the invention is characterized in that the nozzle has a groove in a circumferential wall.

For the nozzle to be separated from the holder, it can be taken up by means of the groove.

The nozzle exchange device according to the invention is characterized in that in the nozzle exchange device a nozzle detachably connected to a holder can be exchanged.

Such a nozzle exchange device is advantageous in that nozzles can be relatively simple to decouple, store and couple therein.

The method according to the invention is characterized in that a device comprising a holder and a detachable nozzle are moved to a nozzle exchange device in which the nozzle is separated from the holder, after which the holder is coupled to another nozzle.

An advantage of such a method is that the holder can be decoupled from a certain nozzle and coupled to a new nozzle in a relatively simple manner by means of the nozzle exchange device.

Another embodiment of the method according to the invention is characterized in that in the nozzle exchange device the device is axially moved in a spacious cavity, after which the nozzle is moved to a narrow cavity connecting to the spacious cavity by means of a displacement transverse to the axial displacement, in which narrow cavity the nozzle is clamped, after which it is separated from the holder by means of an axial displacement, and the holder is moved to another nozzle.

An advantage of such an embodiment is that with a relatively simple lock-like construction (spacious cavity and a narrow enveloping cavity connecting to the spacious cavity) the nozzles can be decoupled from the holder.

A further embodiment of the method according to the invention is characterized in that an identification means situated on the nozzle is scanned by a camera or a laser, after which the nozzle is recognized from the identification means.

An advantage of such an embodiment is that by means of the reading of the identification means by a laser, the identification means can be used both for identification and verification purposes of the nozzles, so that it can be verified whether the right nozzle is attached to the holder.

These and other aspects of the invention are apparent from and will be elucidated with reference to the embodiments described hereinafter.

In the drawings:

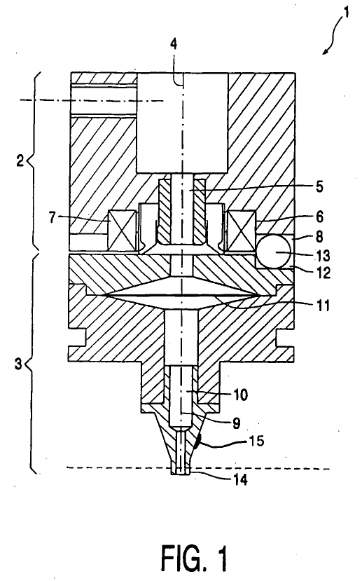

FIG. 1 shows a diagrammatic cross-section of an embodiment of a placement device according to the invention,

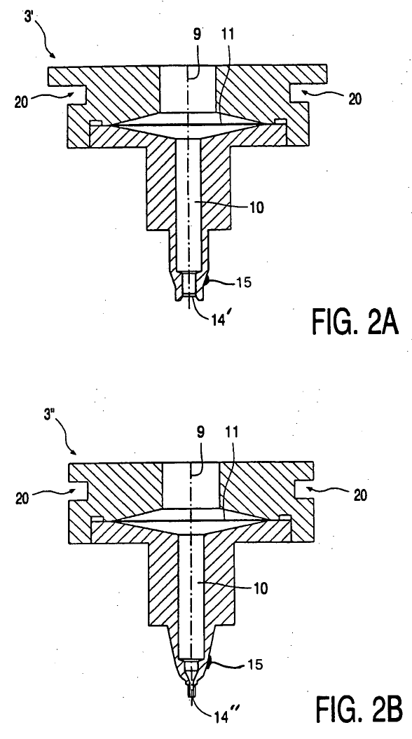

FIGS. 2A-2B diagrammatically show cross-sections of different nozzles of a placement device according to the invention,

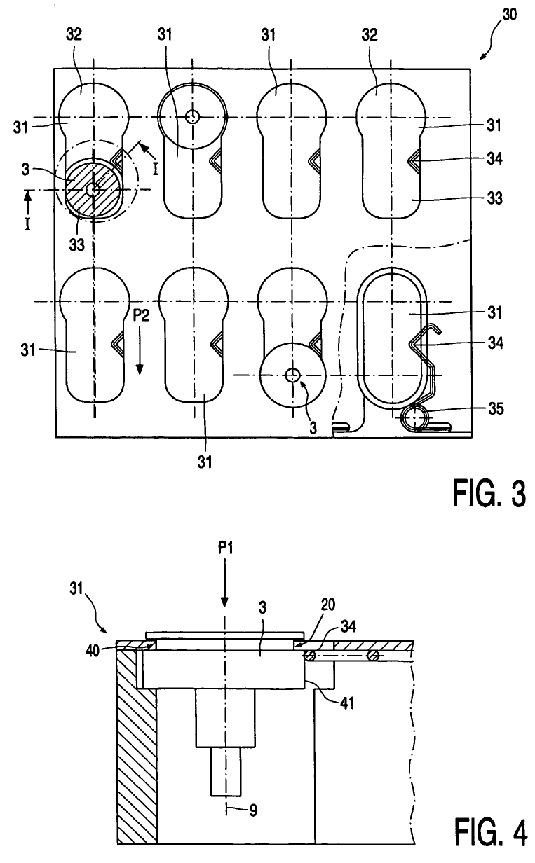

FIG. 3 shows a plan view of a nozzle exchange device according to the invention,

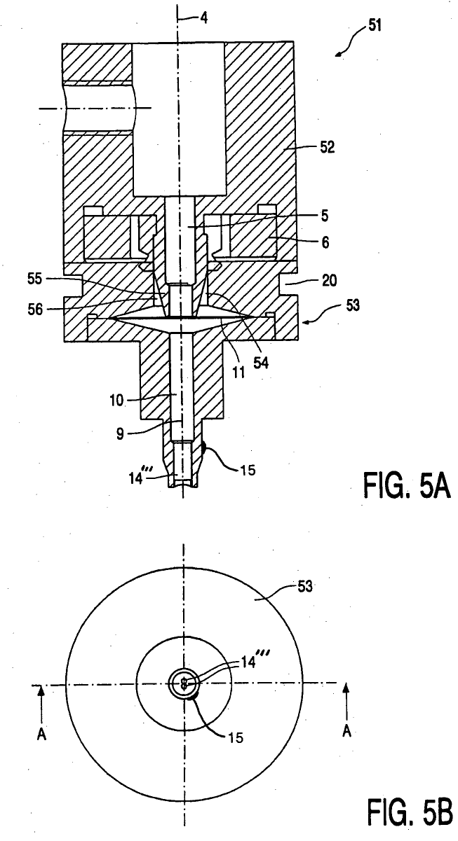

FIG. 4 shows a diagrammatic cross-section of the nozzle exchange device shown along the line I-I in FIG. 3, and

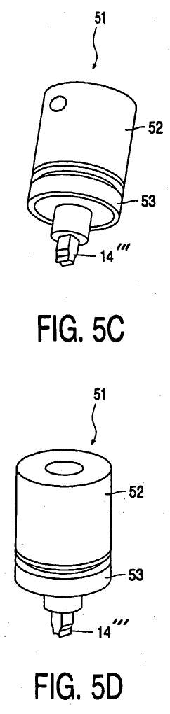

FIGS. 5A-5D show a section, bottom view, perspective view and front view respectively of another embodiment of a placement device according to the invention.

In the drawing Figures the same reference numbers have been used to indicate corresponding components.

FIG. 1 shows a device 1 according to the present invention, which device is suitable for placing components such as, for example, SMDs, Ball Grid Arrays (BGAs), CSPs, SOTs, SOPs, SOICs, PLCCs, QFPs etc. The device 1 comprises a holder 2 and a nozzle 3. The holder 2 has a passage 5 extending along an axis 4 of the holder 2, which passage is connected to a vacuum pump or other vacuum appliance (not shown) on a side facing away from the nozzle 3. The side of the holder 2 facing the nozzle 3 comprises two magnets 6, 7 or a single annular magnet. Furthermore, this side of the holder 2 has three grooves 8 which are arranged around the circumference of the holder 2 120 degrees apart.

The nozzle 3 comprises a duct 10 extending along the axis 9 of the nozzle 3, which duct 10 comprises a filter 11 by means of which dust particles can be received. The side of the nozzle 3 facing the holder 2 is made of a material having magnetic properties, such as iron. This side has three grooves 12 which are arranged 120 degrees apart around the circumference of the nozzle 3.

The nozzle 3 can be detachably connected to the holder 2. The nozzle 3 and the holder 2 are coupled to each other by means of the magnets 6, 7 and aligned to each other by means of the grooves 8, 12 lying opposite each other and spheres 13 located in these grooves. The axis 4 of the passage 5 of the holder 2 then corresponds to the axis 8 of the duct 10 of the nozzle 3, so that the duct 10 and the passage 5 form a whole after coupling. By means of the spheres 13 the nozzle 3 can be simply aligned to the holder 2 in the right position (the position in which the axis 8 of the duct 10 corresponds to the axis 4 of the passage 5). The holder 2 and the nozzle 3 are kept together by the magnetic force of the magnets 6, 7 which acts on the metal contact face of the nozzle 3. A vacuum for picking up a component at the end 14 of the duct 10 can be built up in the duct 10 and the passage 5 by means of a vacuum pump or other vacuum system.

FIGS. 2A-2B show diagrammatic cross-sections of two different embodiments of nozzles 3′, 3″ which have each a different end 14 by which different sorts of components can be picked up in optimum fashion. These nozzles 3′, 3″ can be detachably attached to a holder 2. Each nozzle 3′, 3″ comprises at least a groove 20 extending along the circumference, the function of which groove will become apparent with reference to the FIGS. 3 and 4.

The surface of the end 14 of the duct 10 depends on among other things the dimensions such as the mass of a component, the available space for placing the component on the substrate etc. The nozzle 3′ shown in FIG. 2A is more suitable for picking up large components than the nozzle 3″ shown in 2B, because the surface is larger so that the component is attached to the end 14 in a stabler manner. The nozzle 3″ is more suitable for picking up relatively small components.

FIG. 3 shows a plan view of a nozzle exchange device 30. The nozzle exchange device 30 comprises eight exchange elements 31. Each exchange element 31 has a slotted opening consisting of an opening 32 of a large diameter and a connecting opening 33 of a smaller diameter. Each exchange element 31 has a spring 34 of which one end is located in a chamber 35 and of which the other end is situated between the two openings 32, 33.

FIG. 4 shows a diagrammatic cross-section of a nozzle 3 situated in an exchange element 31.

The operation of the nozzle exchange device 30 will now be briefly discussed. The holder 2 with the nozzle 3 is moved by means of displacement means (not shown) to above an exchange element 31 in the nozzle exchange device 30, after which the device 1 is moved in the direction indicated by arrow PI in an opening 32, until the nozzle is located inside the exchange element 31 and the groove 20 of the nozzle 3 is at the same height as the edge 40. Subsequently, the device 1 is moved in the horizontal direction indicated by the arrow P2 to the opening 33 of the exchange element 31 having the smallest diameter, while the spring 34 is pressed sideways against resilience.

After the horizontal displacement, the nozzle 3 is enclosed by the edge 40 of the opening 33 having the smallest diameter as well as the rebounded spring 34. The spring 34 exerts a force on a wall 41 of the nozzle 3 as can be seen in FIG. 4, so that the nozzle 3 is firmly clamped between the spring 34 and the edge 40 of the exchange element 3 1.

The holder 2 connected to the nozzle 3 is then moved up in vertical direction, in an opposite direction to the arrow P1, while a connecting force, for example between the two magnets of the holder 2 and the metal surface of the nozzle 2, is exceeded so that the nozzle 3 is decoupled from the holder 2.

The holder 2 is then moved to above another nozzle 2 located in the nozzle exchange device 30, after which the holder 2 is detachably coupled to another nozzle 3 by means of, for example, the magnets 6, 7. The device 1 is then moved to the opening 32 having the largest diameter in a direction opposite to the arrow P2 while the tension of the spring 34 is exceeded. As soon as the device 1 is in the opening 33 having the largest diameter, the placement device 1 is moved up in vertical direction.

FIGS. 5A and 5D show another embodiment of a device 51 according to the invention which largely corresponds to the device 1 shown in FIG. 1. The device 51 comprises a holder 52 and a nozzle 53 detachably coupled therewith. The holder 52 comprises a passage 5 extending along an axis 4 of the holder 2, which passage is connected to a vacuum system on a side facing away from the nozzle 53. The holder 52 and the nozzle 53 are detachably coupled to each other by means of an annular magnet 6. The nozzle 53 comprises a duct 10 extending along the axis 9 of the nozzle 53, which duct is suitable at an end 14 for picking up components by means of a vacuum built up in the duct 10. On a side facing away from the end 14 the duct 10 has a funneled end 54 in which there is a protrusion 55 extending from the holder 52. The holder 52 as well as the protrusion 55 have a passage 5 that is connected to the duct 10. The protrusion 55 on a side facing the nozzle 53 has a beveled side 56 which preferably has a subinvolute shape. If a relatively large force is exerted on the nozzle 53 in radial direction relative to the axis 9, the nozzle 53 will tilt relative to the holder 52 and, thanks to the beveled edges 56 will come loose from the holder 52 without damaging it. When the nozzle 53 is attached to the holder 52, the protrusion 56 together with the funneled end 54 serves for centering the nozzle 53 and the holder 52 relative to each other.

The nozzle 53 has a groove 20 extending along the circumference, which groove is, as has already been described above, suitable for removing the nozzle 53 from the holder 52 in a simple way in for example a nozzle exchange device 30. Since the groove 52 is relatively close to the holder 52, no forces will be exerted on the nozzle 53 when the holder 51 and the nozzle 53 are displaced in the nozzle exchange device 30 in the direction indicated by the arrow PI when the spring 34 is pushed aside, so that the nozzle 53 is prematurely separated from the holder 52. Not until the moment when the nozzle 53 is in the opening 33 having a relatively small diameter can the force exerted on the nozzle 53 by the magnet 6 be overcome by moving the holder 52 in a direction opposite to the arrow P1, so that the holder 52 and the nozzle 53 are separated in a simple manner.

It is observed that the passage 5 and the duct 10 cannot only be connected to each other in a coaxial manner but also at an angle.

It is alternatively possible to detachably connect the holder and the nozzle by means of vacuum.

1.-15. (canceled)

16. A component placement device comprising:
a holder that includes a passage; and
a nozzle that includes a duct and that is detachably connected to the holder,
wherein the passage is in fluid communication with the duct.

17. The device as claimed in claim 16, wherein the nozzle is configured to be decoupled from the holder in a radial direction relative to an axis of the duct once a predefined force in radial direction on the nozzle is exceeded.

18. The device as claimed in claim 16, wherein the nozzle is detachably attached to the holder by means of at least one magnet.

19. The device as claimed in claim 16, wherein the holder and the nozzle are axially aligned with each other.

20. The device as claimed in claim 19, wherein the holder and the nozzle have axially engaging elements.

21. The device as claimed in claim 20,
wherein the holder has a protrusion that extends into the duct of the nozzle, and
wherein the passage extends through the protrusion.

22. The device as claimed in claim 16, wherein the holder comprises at least three radially separated grooves.

23. The device as claimed in claim 16, wherein the nozzle comprises at least three radially separated grooves.

24. The device as claimed in claim 23, wherein the holder comprises at least three radially separated grooves that correspond to the grooves of the nozzle.

25. The device as claimed in claim 24, wherein spheres are located between the grooves of the nozzle and the corresponding grooves of the holder.

26. The device as claimed in claim 22, wherein three grooves are radially spaced 120° apart.

27. The device as claimed in claim 23, wherein three grooves are radially spaced 120° apart.

28. The device as claimed in claim 16, wherein the duct and/or the passage have/has a filter.

29. The device as claimed in claim 16, wherein the nozzle includes an identification means.

30. The device as claimed in claim 16, wherein the nozzle has a groove that is provided in a circumferential wall thereof.

31. A nozzle exchange device comprising:
a nozzle;
a holder; and
at least one nozzle exchange element in which the nozzle is configured to be detachably attached to the holder.

32. A method for the exchange of nozzles comprising the steps of:
transporting a device comprising a holder and a first detachable nozzle to a nozzle exchange device;
separating, in the nozzle exchange device, the first nozzle from the holder; and
coupling the holder to a second nozzle.

33. The method as claimed in claim 32, further comprising the steps of: moving the device axially in a large opening in the nozzle exchange device; transporting the nozzle, by means of a move transverse to the axial movement, to a
small opening that is connected to the large opening; clamping the nozzle in the small opening;
separating the nozzle from the holder by means of an axial displacement; and moving the holder to another nozzle.

34. The method as claimed in claim 32, further comprising the step of:
scanning an identification means located on the nozzle by means of a camera or a laser; and
recognizing the nozzle on account of the identification means.
